(19) United States
(12) Patent Application Publication
(10) Pub. No.: US 2022/0286120 A1
(43) Pub. Date: Sep. 8, 2022

(54) Channel loss compensation circuit

(71) Applicant: REALTEK SEMICONDUCTOR CORPORATION, HSINCHU (TW)

(72) Inventors: PO-NING CHEN, HSINCHU (TW); SHAWN MIN, HSINCHU (TW)

(21) Appl. No.: 17/683,783

(22) Filed: Mar. 1, 2022

(30) Foreign Application Priority Data
Mar. 8, 2021 (TW) 110108142

(51) Int. Cl. H03K 5/1252; H03K 17/687

(52) U.S. Cl. CPC H03K 5/1252; H03K 17/6874; H04L 27/01

(57) ABSTRACT

A channel loss compensation circuit utilized in a receiving end of an electronic device includes a load, first and second transistors, first and second current sources, an adjustable capacitor, and an adjustable resistor. The first transistor has a first, second, and third terminals. The first terminal receives an input signal, and the second terminal is coupled to a power supply voltage through the load. The second transistor has a fourth, fifth terminal, and sixth terminals. The fourth terminal receives the input signal, and the fifth terminal is coupled to the power supply voltage through the load. The first current source is coupled between the third terminal and a reference voltage. The second current source is coupled between the sixth terminal and the reference voltage. The adjustable capacitor and the adjustable resistor are coupled between the third terminal and the sixth terminal.

### BACKGROUND OF THE INVENTION

### 1. Field of the Invention

The present invention generally relates to high speed serial links, and, more particularly, to compensation circuits utilized in the receiving end of the high speed serial link.

### 2. Description of Related Art

High speed serial links are common in modern electronic devices which, for example, use Serial Advanced Technology Attachment (SATA), Peripheral Component Interconnect (PCI)-Express (PCIe) or Universal Serial Bus (USB) interfaces to transmit data. Due to the imperfect transmission channel (i.e., inevitable channel losses), signals usually attenuate during transmission. In view of this, the receiving end of the high speed serial link needs to compensate the received signal to obtain a better eye diagram. The better the quality of the eye diagram, the better the performance of the electronic device.

However, channel losses are usually frequency-dependent (i.e., losses are different from frequency to frequency); therefore, to provide a channel loss compensation circuit (which can also be referred to as an equalizer in some applications) that can flexibly adjust the gain-frequency relationship (i.e., the alternate current (AC) response, which can be regarded as the compensation characteristic of the channel loss compensation circuit) has become an important issue in this technical field.

### SUMMARY OF THE INVENTION

In view of the issues of the prior art, an object of the present invention is to provide a channel loss compensation circuit, so as to make an improvement to the prior art.

According to one aspect of the present invention, a channel loss compensation circuit is provided. The channel loss compensation circuit is utilized in a receiving end of an electronic device and includes a load, a first transistor, a second transistor, a first current source, a second current source, an adjustable capacitor, and an adjustable resistor. The first transistor has a first terminal, a second terminal, and a third terminal. The first terminal receives an input signal, and the second terminal is coupled to a power supply voltage through the load. The second transistor has a fourth terminal, a fifth terminal, and a sixth terminal. The fourth terminal receives the input signal, and the fifth terminal is coupled to the power supply voltage through the load. The first current source is coupled between the third terminal and a reference voltage. The second current source is coupled between the sixth terminal and the reference voltage. The adjustable capacitor is coupled between the third terminal and the sixth terminal. The adjustable resistor is coupled between the third terminal and the sixth terminal.

According to another aspect of the present invention, a channel loss compensation circuit is provided. The channel loss compensation circuit is utilized in a receiving end of an electronic device and includes a load, a first transistor, a second transistor, a first current source, a second current source, a capacitor array, and a resistor array. The first transistor has a first terminal, a second terminal, and a third terminal. The first terminal receives an input signal, and the second terminal is coupled to a power supply voltage through the load. The second transistor has a fourth terminal, a fifth terminal, and a sixth terminal. The fourth terminal receives the input signal, and the fifth terminal is coupled to the power supply voltage through the load. The first current source is coupled between the third terminal and a reference voltage. The second current source is coupled between the sixth terminal and the reference voltage. The capacitor array is coupled between the third terminal and the sixth terminal and includes a plurality of capacitors and a plurality of first switches. The resistor array is coupled between the third terminal and the sixth terminal and includes a plurality of resistors and a plurality of second switches. An equivalent capacitance of the capacitor array is related to the number of the first switches that are turned on, and an equivalent resistance of the resistor array is related to the number of the second switches that are turned on.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 illustrates a circuit diagram of a channel loss compensation circuit according to an embodiment of the present invention.

FIGS. 2 and 3 illustrate the AC response of the channel loss compensation circuit in FIG. 1.

FIG. 4 illustrates a circuit diagram of the channel loss compensation circuit according to another embodiment of the present invention.

FIG. 5 illustrates a circuit diagram of the channel loss compensation circuit according to another embodiment of the present invention.

FIG. 6 illustrates a circuit diagram of the channel loss compensation circuit according to another embodiment of the present invention.

FIG. 7 illustrates a pole-changing circuit according to an embodiment of the present invention.

FIG. 8 illustrates a pole-changing circuit according to another embodiment of the present invention.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes channel loss compensation circuits. On account of that some or all elements of the channel loss compensation circuits could be known, the detail of such elements is omitted provided that such detail has little to do with the features of this disclosure, and that this omission nowhere dissatisfies the specification and enablement requirements. A person having ordinary skill in the art can choose components equivalent to those described in this specification to carry out the present invention, which means that the scope of this invention is not limited to the embodiments in the specification.

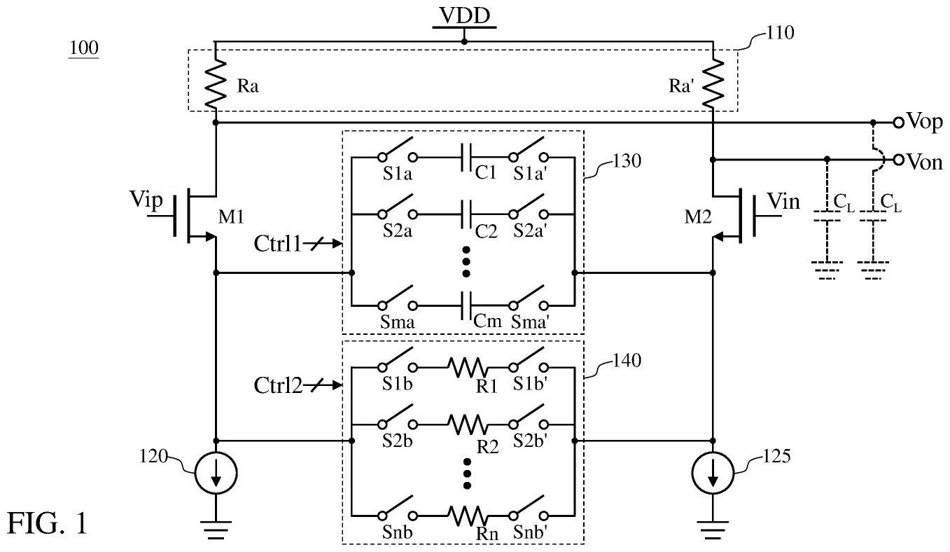

FIG. 1 is a circuit diagram of a channel loss compensation circuit according to an embodiment of the present invention. The channel loss compensation circuit 100 includes a transistor pair (comprising a transistor M1 and a transistor M2), a load 110 (comprising a resistor Ra and a resistor Ra′), a current source 120, a current source 125, an adjustable capacitor (i.e., the capacitor array 130), and an adjustable resistor (i.e., the resistor array 140).

The transistor M1 and transistor M2 are embodied by N-type Metal-Oxide-Semiconductor Field-Effect Transistors (MOSFETs) (hereinafter referred to as NMOS transistors). The gate of the transistor M1 receives the input signal Vip, the drain of the transistor M1 is coupled to the power supply voltage VDD through the resistor Ra of the load 110, and the source of the transistor M1 is coupled to the reference voltage (e.g., ground) through the current source 120. The gate of the transistor M2 receives the input signal Vin, the drain of the transistor M2 is coupled to the power supply voltage VDD through the resistor Ra′ of the load 110, and the source of the transistor M2 is coupled to the reference voltage through the current source 125. The gate of the transistor M1 and the gate of the transistor M2 together form the input terminals of the channel loss compensation circuit 100, and the input signal Vip and the input signal Vin together form a differential input signal Vi. The channel loss compensation circuit 100 compensates the differential input signal Vi and generates a differential output signal Vo, which comprises the output signal Vop and the output signal Von. The drain of the transistor M1 and the drain of the transistor M2 together form the output terminals of the channel loss compensation circuit 100. The output signal Vop is outputted from the drain of the transistor M1, and the output signal Von is outputted from the drain of the transistor M2. The drain of the transistor M1 and the drain of the transistor M2 are respectively coupled to the ground through the load capacitors C_{L}. The load capacitors C_{L} are the load of the channel loss compensation circuit 100 and do not belong to the channel loss compensation circuit 100.

The capacitor array 130, coupled between the source of the transistor M1 and the source of the transistor M2, includes multiple capacitors (C1 to Cm, m>1) and multiple switches (S1a to Sma and S1a′ to Sma′). The switch Spa and the switch Spa′ form a switch pair (1≤p≤m, that is, the capacitor array 130 includes m switch pairs). One end of the capacitor Cp is coupled to the source of the transistor M1 through the switch Spa, and the other end of the capacitor Cp is coupled to the source of the transistor M2 through the switch Spa′. The switches S1a to Sma and the switches S1a′ to Sma′ are controlled by the control signal Ctrl1. In other words, the number of capacitors in the capacitor array 130 that are actually connected in parallel (i.e., the number of capacitors that are connected as a result of the switch pairs electrically connected thereto being turned on) can be controlled by the control signal Ctrl1. In other words, the equivalent capacitance of the capacitor array 130 is controlled by the control signal Ctrl1. The capacitance of the capacitors C1 to Cm can be any value. In some embodiments, the control signal Ctrl1 controls at least one switch pair to be turned on.

The resistor array 140, coupled between the source of the transistor M1 and the source of the transistor M2, includes multiple resistors (R1 to Rn, n>1) and multiple switches (S1b to Snb and S1b′ to Snb′). The switch Sqb and the switch Sqb′ form a switch pair (1≤q≤n, that is, the resistor array 140 includes n switch pairs). One end of the resistor Rq is coupled to the source of the transistor M1 through the switch Sqb, and the other end of the resistor Rq is coupled to the source of the transistor M2 through the switch Sqb′. The switches S1b to Snb and the switches S1b′ to Snb′ are controlled by the control signal Ctrl2. In other words, the number of resistors in the resistor array 140 that are actually connected in parallel (i.e., the number of resistors that are connected as a result of the switch pairs electrically connected thereto being turned on) can be controlled by the control signal Ctrl2. In other words, the equivalent resistance of the resistor array 140 is controlled by the control signal Ctrl2. The resistance of the resistors R1 to Rn can be any value. In some embodiments, the control signal Ctrl2 controls at least one switch pair to be turned on.

In some embodiments, the switches S1a to Sma, the switches S1a′ to Sma′, the switches S1b to Snb, and the switches S1b′ to Snb′ are embodied by transistors, and the control signal Ctrl1 and the control signal Ctrl2 are digital signals. For example, the control signal Ctrl1 includes m bits, each bit corresponding to a switch pair (including the switch Spa and the switch Spa′), and the control signal Ctrl2 includes n bits, each bit corresponding to a switch pair (including the switch Sqb and the switch Sqb′). The control signal Ctrl1 and the control signal Ctrl2 can be generated by the baseband processor of the electronic device (such as a central processing unit (CPU), micro controller, micro processor, digital signal processor (DSP), or their equivalents). In some embodiments, the baseband processor generates the control signal Ctrl1 and the control signal Ctrl2 according to the AC response of the differential input signal Vi.

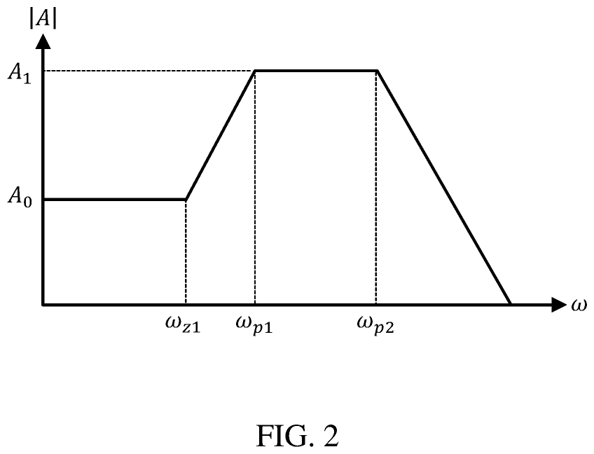

FIG. 2 is the AC response of the channel loss compensation circuit 100. The vertical axis of FIG. 2 is the gain |A| (A₀ and A₁ are the gain values), and the horizontal axis is the angular frequency ω. On the horizontal axis there are the zero point ω_{z1}=1/(RₛCₛ), the pole ωₚ₁=(1+gₘRₛ)/(RₛCₛ) and the pole ωₚ₂=1/(R_{L} C_{L}), where Rₛ is half the equivalent resistance of the resistor array 140, Cₛ is twice the equivalent capacitance of the capacitor array 130, gₘ is the transduction of the transistor M1 or M2, R_{L} is the resistance of the resistor Ra or resistor Ra′, and C_{L} is the capacitance of the load capacitor C_{L}. In some embodiments, the resistor Ra and the resistor Ra′ are identical, the transistor M1 and the transistor M2 are identical, and the current source 120 and the current source 125 are identical. The current source 120 and the current source 125 are used to provide a direct current (DC) bias voltage (i.e., to determine the value of gₘ) to the transistor M1 and the transistor M2, respectively. Therefore, those who implement the present invention can determine the position(s) of the zero point ω_{z1}, the pole ωₚ₁, and/or the pole ωₚ₂ by adjusting the parameters of the components in the channel loss compensation circuit 100.

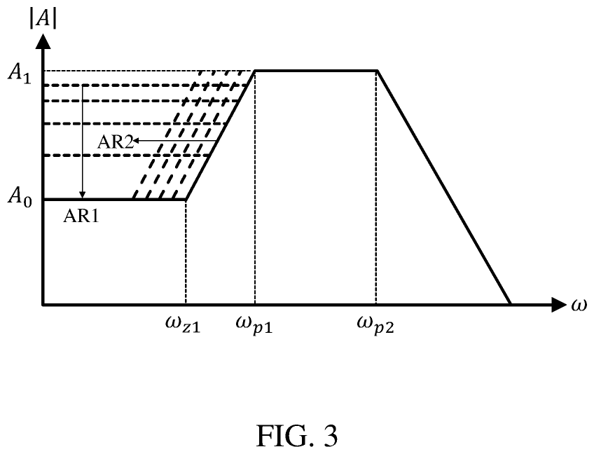

Since the positions of the zero point ω_{z1} and the pole ωₚ₁ are related to the equivalent capacitance of the capacitor array 130 and the equivalent resistance of the resistor array 140, the positions of the zero point ω_{z1} and the pole ωₚ₁ can be changed (i.e., adjusting the compensation characteristics of the channel loss compensation circuit 100) by the control signal Ctrl1 and/or the control signal Ctrl2. For example, please refer to FIG. 3. The larger the resistance Rₛ, the smaller the zero point ω_{z1} (as indicated by the arrow AR1); the larger the capacitance Cₛ, the smaller the pole ωₚ₁ and zero point ω_{z1} (as indicated by the arrow AR2). It can be seen that the channel loss compensation circuit 100 of the present invention can flexibly adjust the AC response, so the channel loss compensation circuit 100 can provide appropriate compensation for various channel losses.

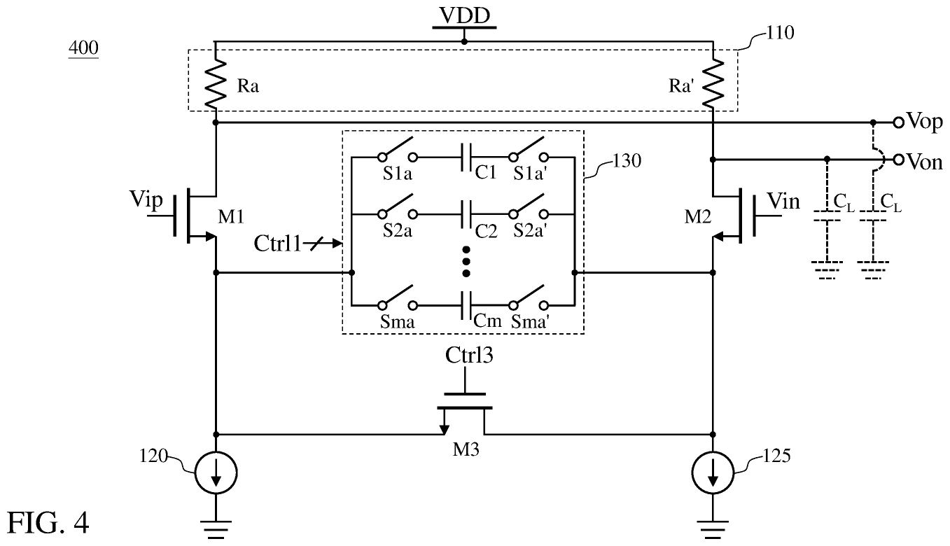

FIG. 4 is a circuit diagram of the channel loss compensation circuit according to another embodiment of the present invention. The channel loss compensation circuit 400 is similar to the channel loss compensation circuit 100, except that the adjustable resistor of the channel loss compensation circuit 400 is embodied by a transistor M3. The source of the transistor M3 is coupled to the source of the transistor M1, the drain of the transistor M3 is coupled to the source of the transistor M2, and the gate of the transistor M3 receives the control signal Ctrl3. The transistor M3 is an active component, and its turn-on resistance is related to the voltage applied to its gate (i.e., the control signal Ctrl3); in other words, the equivalent resistance of the transistor M3 can be changed by the control signal Ctrl3. The relationship between the turn-on resistance of the transistor and the control signal Ctrl3 is well known to people having ordinary skill in the art, and the details are thus omitted for brevity.

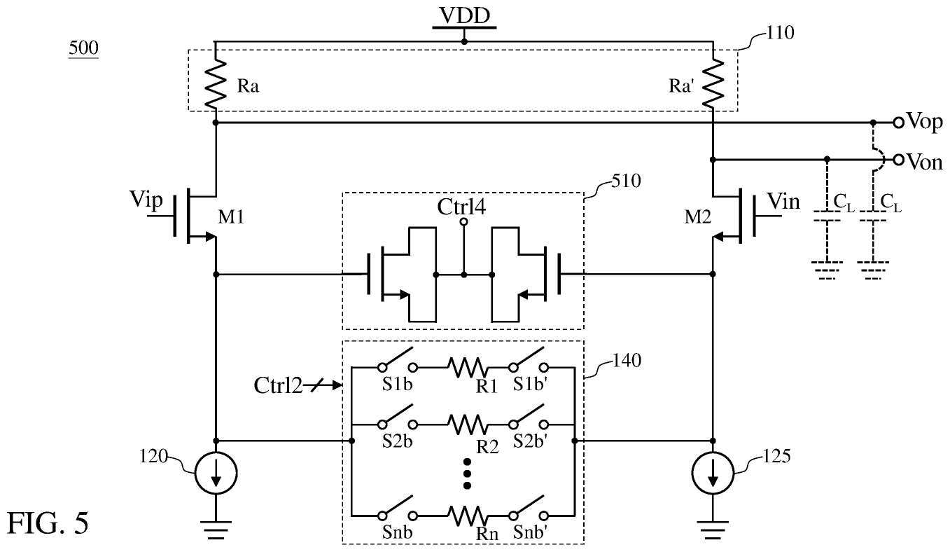

FIG. 5 is a circuit diagram of the channel loss compensation circuit according to another embodiment of the present invention. The channel loss compensation circuit 500 is similar to the channel loss compensation circuit 100, except that the adjustable capacitor of the channel loss compensation circuit 500 is embodied by a varactor 510. One end of the varactor 510 is coupled to the source of the transistor M1, and the other end of the varactor 510 is coupled to the source of the transistor M2. The varactor 510 is an active component, and its equivalent capacitance is related to the voltage applied to it (i.e., the control signal Ctrl4); in other words, the equivalent capacitance of the varactor 510 can be changed by the control signal Ctrl4. The circuit details and operating principles of the varactor are well known to people having ordinary skill in the art and are thus omitted for brevity.

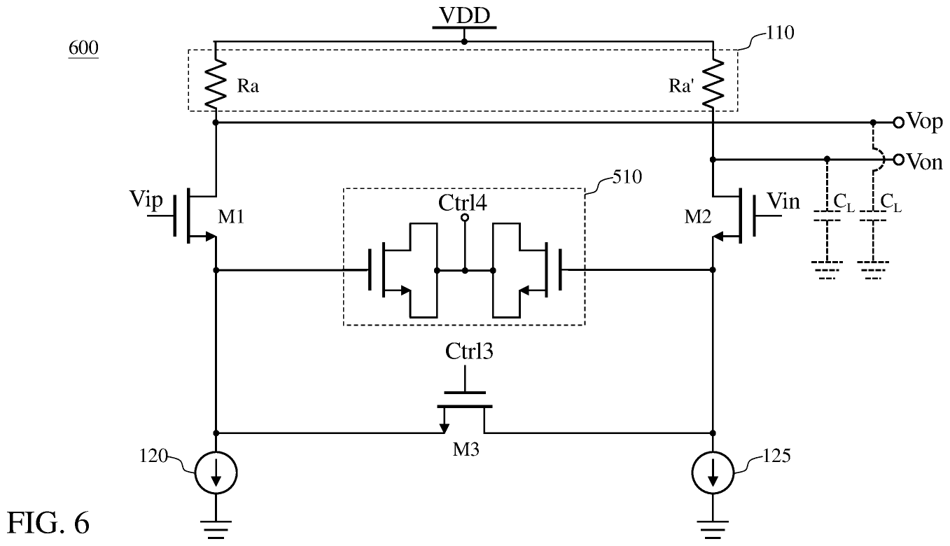

FIG. 6 is a circuit diagram of the channel loss compensation circuit according to another embodiment of the present invention. The adjustable capacitor and adjustable resistor of the channel loss compensation circuit 600 are embodied by the varactor 510 and the transistor M3, respectively.

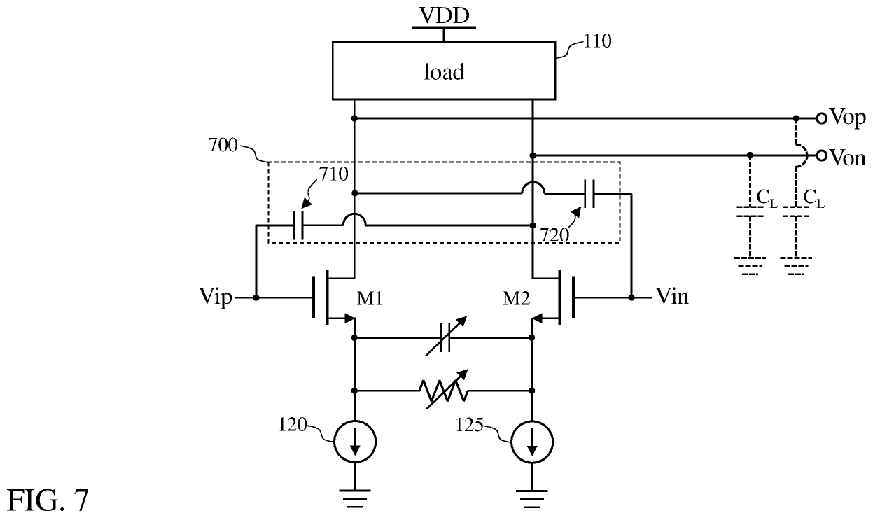

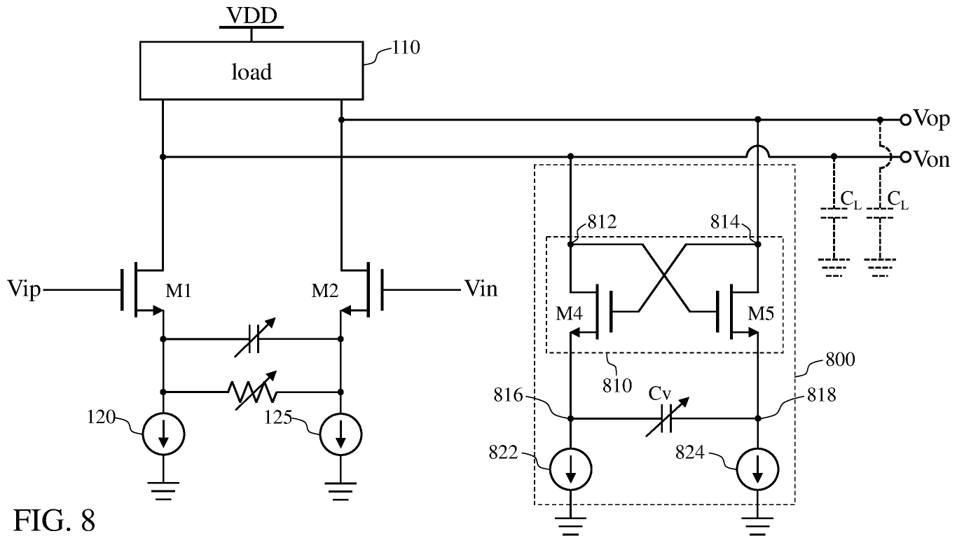

Reference is made to FIG. 2. In some embodiments, the compensation of the intermediate frequency and/or high frequency of the differential input signal Vi can be adjusted by changing the position of the pole ωₚ₂. FIG. 7 and FIG. 8 each show a circuit for adjusting the input loading.

In the embodiment of FIG. 7, the negative capacitance circuit 700 is coupled to the drain of the transistor M1 and the drain of the transistor M2, and includes a capacitor 710 and a capacitor 720. More specifically, the capacitor 710 is coupled between the gate of the transistor M1 and the drain of the transistor M2, and the capacitor 720 is coupled between the gate of the transistor M2 and the drain of the transistor M1. When the capacitance of the negative capacitance circuit 700 is appropriately selected, the input loading of the circuit in FIG. 7 can be effectively reduced.

In the embodiment of FIG. 8, the negative capacitance circuit 800 is coupled to the drain of the transistor M1 and the drain of the transistor M2, and includes a cross-coupled transistor pair 810, an adjustable capacitor Cv, and the current sources 822 and 824. More specifically, the cross-coupled transistor pair 810 includes a transistor M4 and a transistor M5. The drain of the transistor M4 is coupled to the gate of the transistor M5, and the drain of the transistor M5 is coupled to the gate of the transistor M4. The negative capacitance circuit 800 has four terminals: 812, 814, 816, and 818, of which the terminal 812 (i.e., the drain of the transistor M4 and the gate of the transistor M5) is coupled to the drain of the transistor M1, and the terminal 814 (i.e., the drain of the transistor M5 and the gate of the transistor M4) is coupled to the drain of the transistor M2, the terminal 816 (i.e., the source of the transistor M4) is coupled to the reference voltage through the current source 822, and the terminal 818 (i.e., the source of the transistor M5) is coupled to the reference voltage through the current source 824. The adjustable capacitor Cv is coupled between the terminal 816 and the terminal 818. Adjusting the current values of the current sources 822 and 824 can change the equivalent capacitance of the negative capacitance circuit 800, which in turn changes the input loading of the circuit in FIG. 8.

The embodiment of FIG. 7 or FIG. 8 can be combined with the embodiment of FIG. 1, FIG. 4, FIG. 5, or FIG. 6. The combined circuit can flexibly adjust the position(s) of the zero point ω_{z1}, the pole ωₚ₁, and/or the pole ωₚ₂ in FIG. 2.

In summary, the channel loss compensation circuit of the present invention can flexibly adjust the compensation characteristics (i.e., the relationship between the gain and the frequency), and its effects include a smaller jitter in the eye diagram and the obtaining of the convergence point of the better minimum edge of the eye diagram. The channel loss compensation circuit of the present invention can improve the eye diagram of the receiving end of the high speed serial link, which, in other words, can improve the performance of the receiving end of the high speed serial link.

The transistors in the embodiments discussed above are not limited to the NMOS transistors, and people having ordinary skill in the art can replace the NMOS transistors with P-type metal-oxide-semiconductor (PMOS) field-effect transistors based on the above discussions. The channel loss compensation circuit of the present invention can also be utilized in the managed switches conforming to the XSGMII/TGR specification.

The shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A channel loss compensation circuit utilized in a receiving end of an electronic device, comprising:
a load;
a first transistor having a first terminal, a second terminal, and a third terminal, wherein the first terminal receives an input signal, and the second terminal is coupled to a power supply voltage through the load;
a second transistor having a fourth terminal, a fifth terminal, and a sixth terminal, wherein the fourth terminal receives the input signal, and the fifth terminal is coupled to the power supply voltage through the load;
a first current source, coupled between the third terminal and a reference voltage;
a second current source, coupled between the sixth terminal and the reference voltage;
an adjustable capacitor, coupled between the third terminal and the sixth terminal; and
an adjustable resistor, coupled between the third terminal and the sixth terminal.

2. The channel loss compensation circuit of claim 1, wherein the adjustable capacitor comprises:
a plurality of capacitors; and
a plurality of switches, coupled to the capacitors;
wherein an equivalent capacitance of the adjustable capacitor is related to the number of switches that are turned on.

3. The channel loss compensation circuit of claim 2, wherein the adjustable resistor comprises:
a third transistor having a seventh terminal, an eighth terminal, and a ninth terminal;
wherein the eighth terminal is coupled to the third terminal, the ninth terminal is coupled to the sixth terminal, and an equivalent resistance of the adjustable resistor is related to a voltage applied to the seventh terminal.

4. The channel loss compensation circuit of claim 1, wherein the adjustable resistor comprises:
a plurality of resistors; and
a plurality of switches, coupled to the resistors;
wherein an equivalent resistance of the adjustable resistor is related to the number of switches that are turned on.

5. The channel loss compensation circuit of claim 4, wherein the adjustable capacitor is embodied by a varactor.

6. The channel loss compensation circuit of claim 1, wherein the adjustable capacitor is embodied by a varactor, the adjustable resistor is embodied by a third transistor, the third transistor has a seventh terminal, an eighth terminal, and a ninth terminal, the eighth terminal is coupled to the third terminal, the ninth terminal is coupled to the sixth terminal, and an equivalent resistance of the adjustable resistor is related to a voltage applied to the seventh terminal.

7. The channel loss compensation circuit of claim 1, further comprising:
a negative capacitance circuit, coupled to the second terminal and the fifth terminal.

8. The channel loss compensation circuit of claim 7, wherein the negative capacitance circuit comprises:
a first capacitor, coupled between the first terminal and the fifth terminal; and
a second capacitor, coupled between the fourth terminal and the second terminal.

9. The channel loss compensation circuit of claim 7, wherein the negative capacitance circuit comprises:
a cross-coupled transistor pair, having a seventh terminal, an eighth terminal, a ninth terminal, and a tenth terminal;
a third current source; and
a fourth current source;
wherein the seventh terminal is coupled to the second terminal, the eighth terminal is coupled to the fifth terminal, the ninth terminal is coupled to the reference voltage through the third current source, and the tenth terminal is coupled to the reference voltage through the fourth current source.

10. A channel loss compensation circuit utilized in a receiving end of an electronic device, comprising:
a load;
a first transistor having a first terminal, a second terminal, and a third terminal, wherein the first terminal receives an input signal, and the second terminal is coupled to a power supply voltage through the load;
a second transistor having a fourth terminal, a fifth terminal, and a sixth terminal, wherein the fourth terminal receives the input signal, and the fifth terminal is coupled to the power supply voltage through the load;
a first current source, coupled between the third terminal and a reference voltage;
a second current source, coupled between the sixth terminal and the reference voltage;
a capacitor array, coupled between the third terminal and the sixth terminal and comprising a plurality of capacitors and a plurality of first switches; and
a resistor array, coupled between the third terminal and the sixth terminal and comprising a plurality of resistors and a plurality of second switches;
wherein an equivalent capacitance of the capacitor array is related to the number of the first switches that are turned on, and an equivalent resistance of the resistor array is related to the number of the second switches that are turned on.

11. The channel loss compensation circuit of claim 10, further comprising:
a negative capacitance circuit, coupled to the second terminal and the fifth terminal.

12. The channel loss compensation circuit of claim 11, wherein the negative capacitance circuit comprises:
a first capacitor, coupled between the first terminal and the fifth terminal; and
a second capacitor, coupled between the fourth terminal and the second terminal.

13. The channel loss compensation circuit of claim 11, wherein the negative capacitance circuit comprises:
a cross-coupled transistor pair, having a seventh terminal, an eighth terminal, a ninth terminal, and a tenth terminal;
a third current source; and
a fourth current source;
wherein the seventh terminal is coupled to the second terminal, the eighth terminal is coupled to the fifth terminal, the ninth terminal is coupled to the reference voltage through the third current source, and the tenth terminal is coupled to the reference voltage through the fourth current source.
